(19) United States
(12) Patent Application Publication
(10) Pub. No.: US 2013/0137235 A1
(43) Pub. Date: May 30, 2013

(54) MOS TRANSISTOR USING STRESS CONCENTRATION EFFECT FOR ENHANCING STRESS IN CHANNEL AREA

(71) Applicants: Qi Yu, Chengdu (CN); Xiangzhan Wang, Chengdu (CN); Ning Ning, Chengdu (CN); Jingchun Li, Chengdu (CN); Hongdong Yang, Chengdu (CN); Xianwei Ying, Chengdu (CN); Weijie Zhou, Chengdu (CN); Bin Jiang, Chengdu (CN); Yong Wang, Chengdu (CN)

(72) Inventors: Qi Yu, Chengdu (CN); Xiangzhan Wang, Chengdu (CN); Ning Ning, Chengdu (CN); Jingchun Li, Chengdu (CN); Hongdong Yang, Chengdu (CN); Xianwei Ying, Chengdu (CN); Weijie Zhou, Chengdu (CN); Bin Jiang, Chengdu (CN); Yong Wang, Chengdu (CN)

(73) Assignee: University of Electronic Science and Technology of China, Chengdu (CN)

(21) Appl. No.: 13/512,415

(22) PCT Filed: Apr. 22, 2011
(86) PCT No.: PCT/CN2011/073177

§ 371 Date: May 29, 2012

(30) Foreign Application Priority Data
Jul. 15, 2010 (CN) 201010227112.2
Nov. 11, 2010 (CN) 201010539413.9

(51) Int. Cl. H01L 29/66

(52) U.S. Cl. CPC H01L 29/66477
USPC 438/294

(57) ABSTRACT

A MOS transistor (60, 62) is provided. The structure of the transistor (60, 62) includes: a semiconductor substrate (10), a channel area (20, 24), source/drain regions (22, 26), a gate (30, 32), a gate insulating layer (11), a shallow trench isolation region (12), a passive layer (50, 52), and holes (40, 42) formed with a certain distance to the gate insulating layer (11). Wherein both the shapes of the holes (40, 42) and the Young's modulus' difference between the material in the holes (40, 42) and that around the holes (40, 42) contribute to the stress concentration effect, thus the stress in the channel area (20, 24) is enhanced. The structure of the transistor (60, 62) can greatly reduce the stress attenuation during the transmission from stress resource to the sensitive region, and concentrate the stress in the sensitive region. The structure can be involved in large size device, especially.

### TECHNICAL FIELDS

The present invention generally relates to a semiconductor device and, more particularly, to a technique of improving performance in stress enhanced MOS (metal-oxide-semiconductor) transistor.

### BACKGROUND

The manufacturing technology of semiconductor device has come into nanometer era, introducing stress into the semiconductor devices by Strained-Si technology can increase carrier mobility in the stress-sensitive regions (such as the channel of MOS transistors; the BE junction and BC junction of bipolar transistors etc.) of the devices. The device performance is improved accordingly (including to improve the current driving capability, device speed and to reduce power consumption.) It has been known that introducing tensile stress into the channel of N-type metal oxide semiconductor field-effect transistor (NMOSFET) can enhance the performance of NMOSFET, and introducing compressive stress into the channel of P-type metal oxide semiconductor field-effect transistor (PMOSFET) can enhance the performance of PMOSFET. Moreover, the process of Strained-Si is compatible with existing semiconductor device technology. It does not need to make great changes to existing semiconductor device technology.

At present, the widely used Stained-Si technology is mainly composed of global strain technique and local strain technique. In global strain, the stress is induced by the substrate, and usually biaxial cover all the devices on the substrate. Technique that can produce the global strain includes Semiconductor on Insulator (SOI), SiGe on Insulator (SGOI), and SiGe virtual substrate etc. Local strain technique usually applies stress to the sensitive region of the semiconductor device. Local strain technique mainly contains embedded SiGe or SiC in source and drain, Dual Stress Layers (DSL) and Shallow Trench Isolation (STI). The process of global strain is complex and the cost is high, while the process of local strain technique is rather simple, and compatible with CMOS technology. With the local strain technique, it needs only a slight increase in costs to improve the performance of semiconductor devices. It has drawn much attention in the industry. FIG. 1 is a graph of complementary metal oxide semiconductor field-effect transistor using a variety of strain technology. The left side of the figure is the N-channel field-effect transistor (NMOSFET), and the right side is the P-channel field-effect transistor (PMOSFET). In FIG. 1, the insulating layer 1 can produce global stress. The passivation layer 50/52, the shallow trench isolation 12 and the source and drain regions 22 embedded silicon carbide (SiC) and the source and drain regions 26 embedded silicon germanium (SiGe) can produce local stress.

The local strain technology at present, however, still has some insufficient: (1) It has a certain distance from the stress source to the sensitive areas (shown in FIG. 1, the channel region of the field-effect transistor 22/24) in above methods, the farther distance from the channel region 22/24, the more attenuation of the stress. Take the STI technology as an example, the stress induced by STI needs to pass through the source and drain region in order to reach the channel edge. Moreover, in stress transmission from channel edge to channel center, the stress is influenced by the gate 30/32 above the channel and the bulk silicon 10 below the channel, as a results, the stress distribution in the channel 1 is “U” shape accordingly. More precisely, the stress in channel is inversely proportional to the distance between the stress source and the channel. (2) There are high-temperature processes in semiconductor device fabrication; high temperature can partially cause stress relaxing. DSL technology, for example, its post-process generally includes process steps of at least 450° C. high temperature, therefore, it must make the channel stress partial relaxing. In summary, the above local strain methods are limited by the size of the device and the manufacturing process, the greater size of the device, the smaller channel region stress. This is also the reason that conventional strained silicon technology is only suitable for device process below 90 nm. For larger size (130 nm, 180 nm or more) devices, the performance enhancement by the above methods nearly disappears.

### SUMMARY

The technical problem that the invention to solve is to improve the device performance avoiding the limitations of existing Strained-Si technology, and to provide a MOS transistor using stress concentration effect, which improves the channel stress to enhance the device performance.

The technical solution adopted to solve the described problems is utilizing stress concentration effect to improve the channel stress of MOS transistor, including the semiconductor substrate, the channel region, the source and drain region, gate, the gate insulating layer, the shallow trench isolation areas and the passivating layer. The method is characterized by forming voids at a certain distance away from the gate insulating layer. These holes have different shape and Young's modulus to concentrate the stress in channel region and enlarge it. The voids can be produced by etching process, such as plasma etching. The voids can be filled with a material of lower Young's modulus than Si, resulting in the difference of Young's modulus with the surrounding material.

In material mechanics and structural mechanics, sudden changes emerge in material cross section due to discontinuous material, cracks components and other reasons. Sudden changes can lead to produce a great stress on a local area. In generally, this stress is far greater than the nominal stress or average stress. This phenomenon is called stress concentration. The present invention is based on existing Strained-Si process to form a hole at a certain distance away from the gate insulating layer in MOS transistor, resulting in a sudden change in cross section and material incontinuity, which can induce stress concentration effect to enhance the stress in the sensitive region of the MOS transistor. Experiments show that the stress will concentrate in the edges and corners if the hole is made with angular shape; holes filled with a low Young's modulus material can make the stress concentrating around the holes; the larger difference between the Young's modulus of material inside and outside of holes, the greater stress concentrated. Holes without any material (vacuum or process atmosphere) inside of themselves have a lower Young's modulus than the surrounding semiconductor material.

One alternative approach is to form the hole below the gate insulating layer, as described, 20˜25 nm away from the gate insulating layer. In this approach, the hole is etched 20˜25 nm away from the gate insulating layer below the channel between the source and drain regions in the bulk silicon before the growth of the gate insulating layer. The hole is filled with materials (such as SiO₂) of lower Young's modulus than that of the bulk silicon around the channel. Because the stress concentration effect of the single hole is not sufficient, multi-holes structure can be utilized to increase the stress concentration region. The distance between the holes depends on the device size (channel length), generally, is 2˜40 nm.

Another alternative approach is to form the hole on the top of the gate insulating layer, as described, 5˜10 nm away from the gate insulating layer. In this approach, the gate structure is made by two steps. The first step is the deposition of gate with a certain thickness, in which a hole is etched subsequently. The distance from the hole to the gate insulating layer is generally 5˜10 nm. The second step is to continue the deposition of the gate until the thickness of the gate reaches the requirements of process. The approach can also be a multi-holes structure, the distance between the holes, generally, is 2˜40 nm.

Another approach is to formation the holes on the top of the gate insulating layer and below the gate insulating layer which can be regarded as a combination of above-mentioned two approaches. It can also be a multi-holes structure.

Holes of the present invention can also be located in the side-wall of the gate on both sides or in the source/drain region of channel on both sides, which can also produce the stress concentration effect. Holes located in the source/drain region of channel on both sides are 30˜50 nm away from the surface of bulk silicon, while 5˜15 nm away from the surface of bulk silicon for holes located in the side-wall of the gate on both sides.

A specific shape of holes is prism. Since the stress is concentrated at the edges, corners, choosing the appropriate shape of the holes can control the stress concentration area. For example, regular prismatic (regular hexahedron) holes benefit easy implementation for relative simple etching process, and easy controlling of stress concentration location, for that the stress concentration points are uniformly distributed in the four edges of the bottom and the top surface.

The beneficial effect of the present invention is to greatly reduce the attenuation of stress passed from the stress source to the stress sensitive areas and to concentrate the stress on the stress sensitive regions, achieving greater device performance improvement accordingly. The present invention, in particular, can be used for large-size devices, because the larger size of the device, the stress source is farther away from the stress sensitive areas of the device. Stress concentration features of the present invention can eliminate the stress attenuation effect with the device size increasing.

### BRIEF DESCRIPTION OF THE DRAWINGS

FIG. 1 is a schematic cross-sectional view of the existing technology of the MOS transistors.

FIG. 2 is a schematic cross-sectional view of the MOS transistor of embodiment 1.

FIG. 3 is a schematic view of horizontal multi-holes structure.

FIG. 4 is a schematic view of the simulation results of output characteristics of MOS transistor in embodiment 1.

FIG. 5 is a schematic cross-sectional view of the MOS transistor of embodiment 2.

FIG. 6 is a schematic view of distribution of stress in the channel of the MOS transistor.

FIG. 7 is a schematic cross-sectional view of the MOS transistor of embodiment 3.

FIG. 8 is a schematic cross-sectional view of the MOS transistor of embodiment 4.

FIG. 9 is a schematic view of vertical multi-holes structure.

FIG. 10 is a schematic cross-sectional view of the MOS transistor of embodiment 5.

In the figure: 1—insulating layer; 10—semiconductor substrate; 11—gate insulating layer; 12—shallow trench isolation area; 20—NMOSFET well (P well) also known as the channel region; 22—NMOSFET source and drain regions; 24—PMOSFET well (N well) or the channel region; 26—PMOSFET source and drain regions; 30—NMOSFET gate; 32—PMOSFET gate; 40—holes in the NMOSFET; 42—holes in the PMOSFET; 50—passivation layer (tensile stress SiN layer); 52—passivation layer (compressive stress SiN layer); 60—NMOSFET; 62—PMOSFET.

### DETAILED DESCRIPTION OF THE EMBODIMENT

The following is the detailed description of the technical solutions about the invention, combining with figures and embodiments.

### Embodiment 1

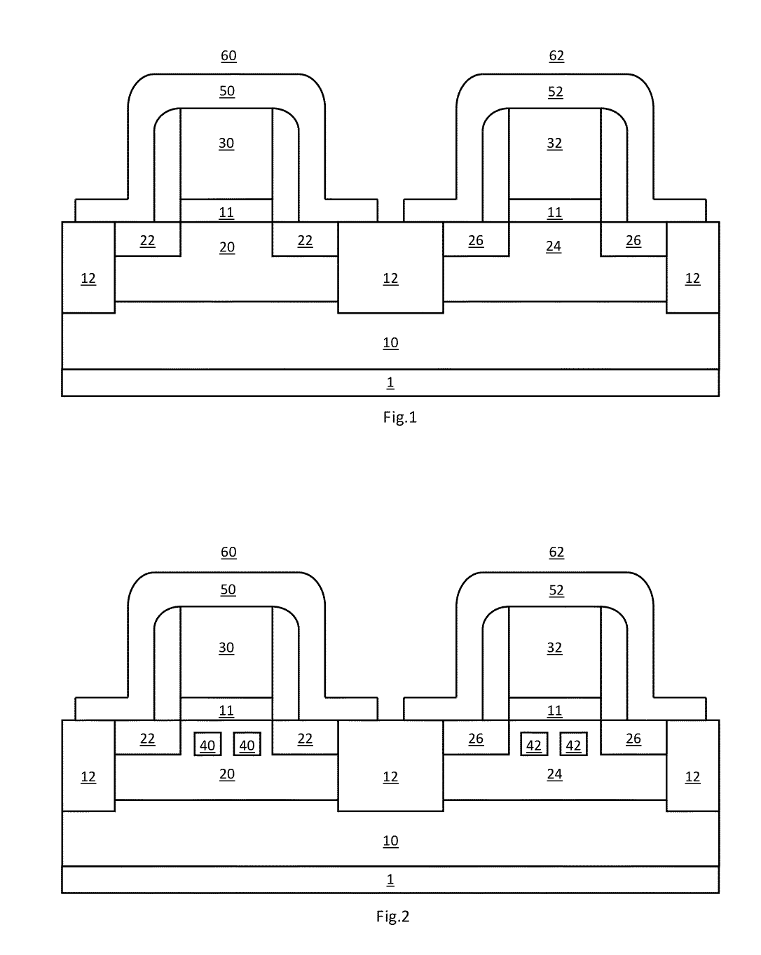

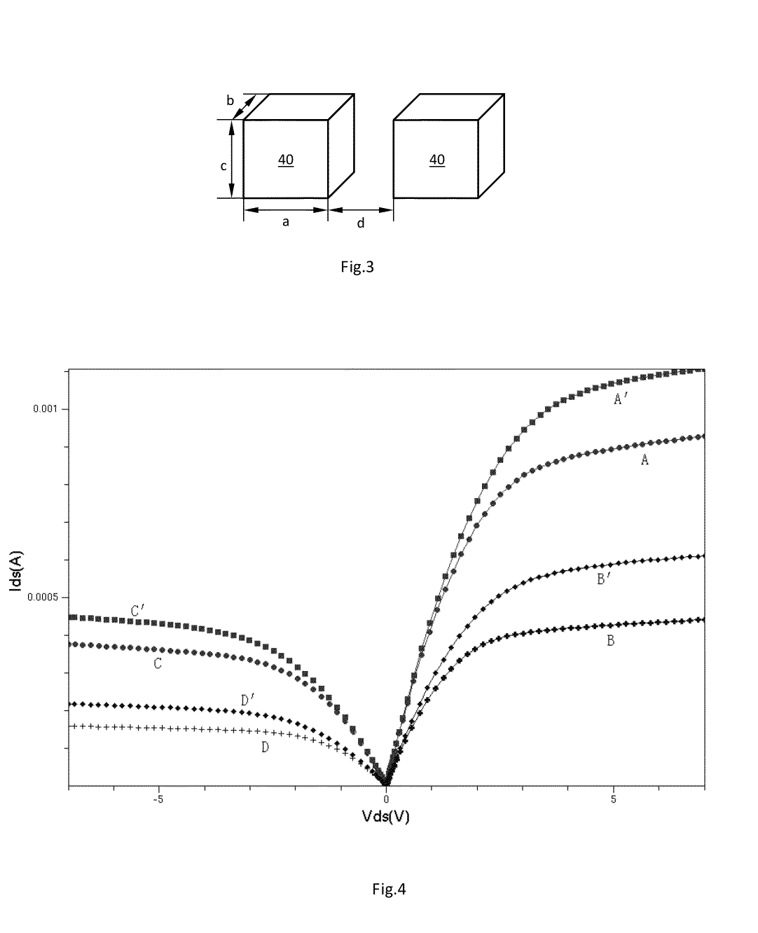

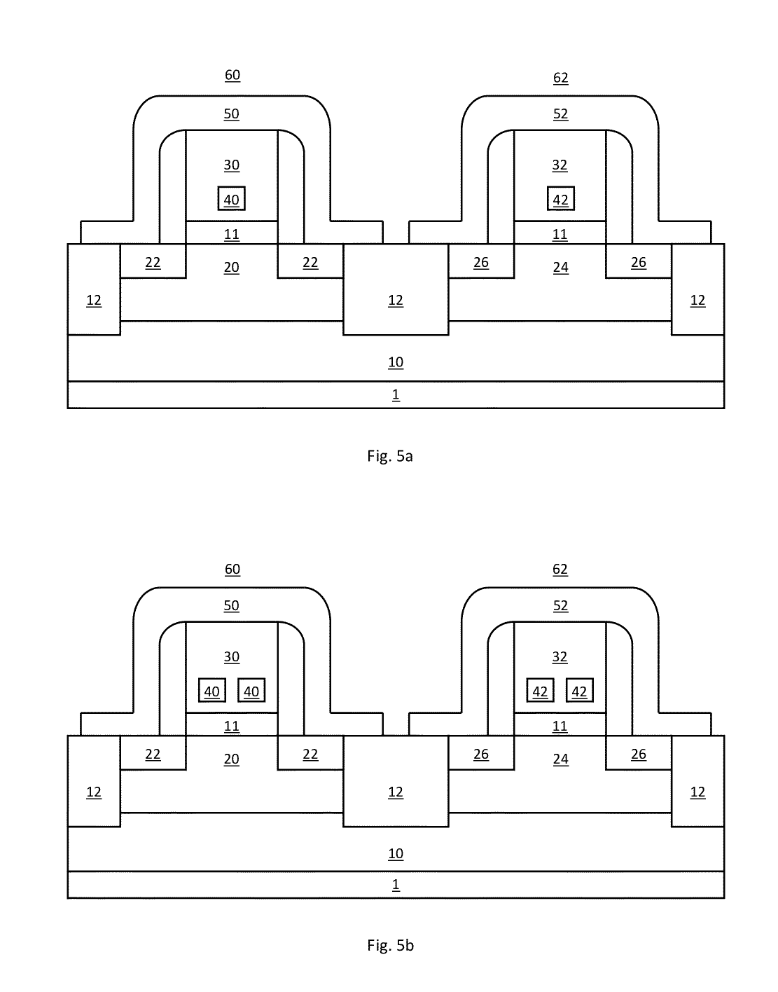

FIG. 2 is the cross-sectional view of this device, containing the insulator layer 1, the semiconductor substrate 10, the channel region 20/24, source/drain 22/26, gate 30/32, the insulator layer of gate 11, the shallow trench isolation area 12 and the passivating layer 50/52. The channel length is 0.5 μm in this embodiment, its manufacturing process, basically identical with the conventional CMOS manufacturing process, in addition to etching two rectangular shape holes 40/42, height c of 150 nm, length a of 200 nm, width d of 1000 nm (consistent with the channel width, same below) and distance d of 30 nm, below the insulator layer of gate 11 25 nm before growing it, shown in the FIG. 3. The shape of the holes is compatible with the crystal structure of the semiconductor substrate to facilitate the etching. The Young's modulus of the holes 40/42, filled with SiO₂ is lower than the surrounding bulk silicon material. In the case, the shape of holes 40/42 promotes the stress to concentrate in the rectangular edges, and because of the lower Young's modulus in the holes than the surrounding bulk silicon material, the stress concentrates to the outside set of holes, making the concentration region near to the channel, and the multi-holes structure contributes to the uniformity of the channel's stress concentration. The electrical properties (I_{ds}-V_{ds} curve in on state) of this device are shown in FIG. 4. Curve A is I_{ds}-V_{ds} curve of conventional NMOSFET with the W/L ratio=1/0.5, A′ is for this case; C is I_{ds}-V_{ds} curve of conventional PMOSFET with the W/L ratio=1/0.5, C′ is for this case. The drive current of NMOSFET has 19.5% increase in the case (compare A with A′); PMOSFET has 18.4% increase (compare C with C′). FIG. 4 also gives the I_{ds}-V_{ds} curve B, B and D, D′ of conventional device and the hole structure device with the W/L=1/0.8, in which the drive current of NMOSFET has 38.6% increase (compare B with B′); PMOSFET has 37.5% (compare D with D′). It can be seen that the improvement of the performance is more obvious for large devices.

### Embodiment 2

In this case, the structure is basically similar to that in embodiment 1 in addition to the position of holes 40/42, shown in FIG. 5. The manufacture procedure of the device has two steps, firstly, depositing a certain thickness of the gate, in which etching the holes 40/42, the holes 40/42 are filled with low Young's modulus material, secondly, continuing to depositing the gate until the total height of the gate meets the requirement of process target. The embodiment is described by the following three schemes:

Schemes 1:

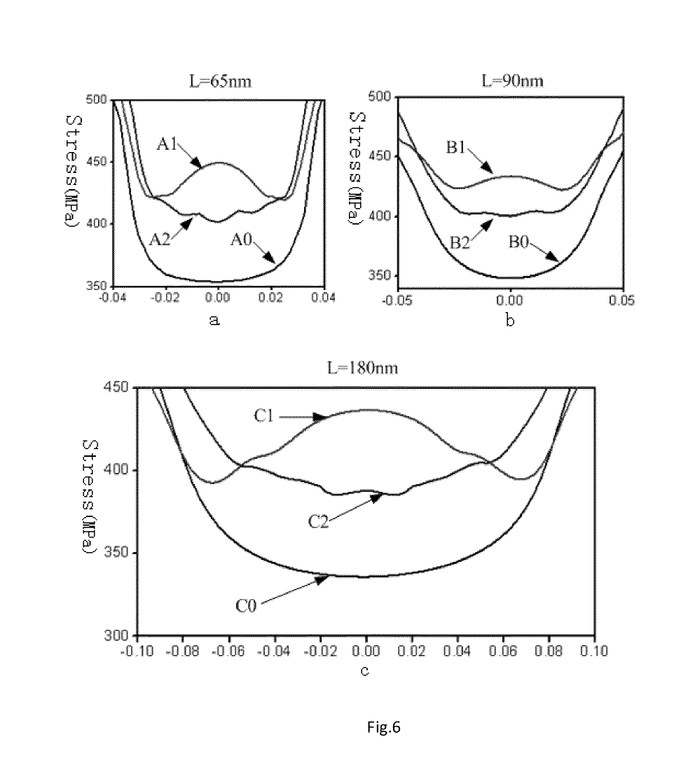

The channel length L=65 nm in the case. Two structures of different holes parameter are designed in the scheme. In first structure, height c of the hole 40/42 is 50 nm, length a is 40 nm and there is only one hole, filled with the low Young's modulus material SiO₂, the distance from the gate insulating layer 11 is 5 nm, seen in FIG. 5(a), the channel stress distribution is Al shown in FIG. 6(a), comparing to the stress distribution AO of conventional devices without hole, the maximum stress increases 24.5%; In second structure, height c of the holes 40/42 is 50 nm, length a is 20 nm and there are two holes, filled with the low Young's modulus material SiO₂, the distance d between the holes is 20 nm, the distance from the gate insulating layer is 5 nm, it can be seen in FIG. 5(b), the channel stress distribution is A2 shown in FIG. 6(a), comparing to the stress distribution AO of conventional devices without holes, the maximum stress increases 13.2%.

Schemes 2:

The channel length L=90 nm in the case. Two structures of different holes parameter are designed in the scheme. In first structure, height c of the holes 40/42 is 60 nm, length a is 60 nm and there is only one hole, filled with the low Young's modulus material SiO₂, the distance from the gate insulating layer 11 is 5 nm, seen in FIG. 5(a), the channel stress distribution is B1 shown in FIG. 6(b), comparing to the stress distribution BO of conventional devices without hole, the maximum stress increases 28.9%; In second structure, height c of the holes 40/42 is 60 nm, length a is 30 nm and there are two holes, filled with the low Young's modulus material SiO₂, the distance d between the holes is 30 nm, the distance from the gate insulating layer is 5 nm, it can be seen in FIG. 5(b), the channel stress distribution is B2 shown in FIG. 6(b), comparing to the stress distribution BO of conventional devices without holes, the maximum stress increases 14.5%.

Schemes 3:

The channel length L=180 nm in the case. Two structures of different holes parameter are designed in the scheme. In first structure, height c of the hole 40/42 is 90 nm, length a is 90 nm and there is only one hole, filled with the low Young's modulus material SiO₂, the distance from the gate insulating layer 11 is 5 nm, seen in FIG. 5(a), the channel stress distribution is C1 shown in FIG. 6(c), comparing to the stress distribution CO of conventional devices without hole, the maximum stress increases 31.3%; In second structure, height c of the holes 40/42 is 90 nm, length a is 40 nm and there are two holes, filled with the low Young's modulus material SiO₂, the distance d between the holes is 30 nm, the distance from the gate insulating layer is 5 nm, it can be seen in FIG. 5(b), the channel stress distribution is C2 shown in FIG. 6(c), comparing to the stress distribution CO of conventional devices without holes, the maximum stress increases 17.8%.

### Embodiment 3

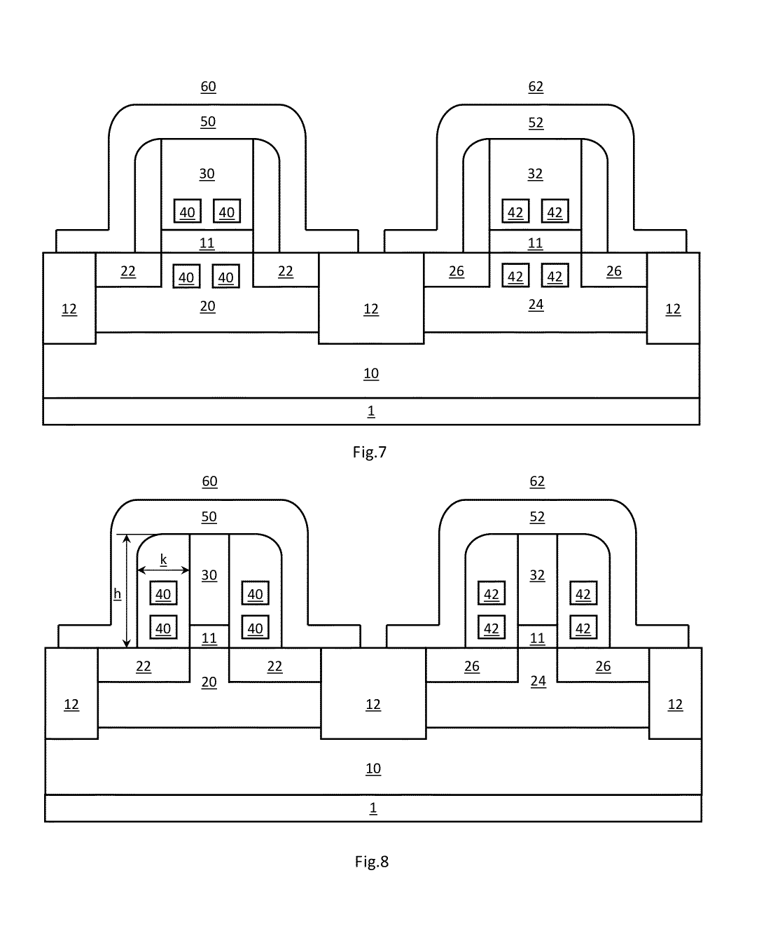

In this case the device structure is shown in FIG. 7. Two holes 40/42 are etched at the top of 5 nm and below the 25 nm from the gate insulating layer, other structures can be seen as the description of embodiment 1.

### Embodiment 4

In this case the device structure is shown in FIG. 8. The width k of the side wall is 100 nm, height h is 240 nm, the holes 40/42 locate in the side wall, holes parameters: c=90 nm, a=50 nm, d=30 nm (shown in FIG. 9), there are two holes, the distance from the below hole to the silicon surface is 10 nm, the holes are filled with the low Young's modulus material SiO₂.

### Embodiment 5

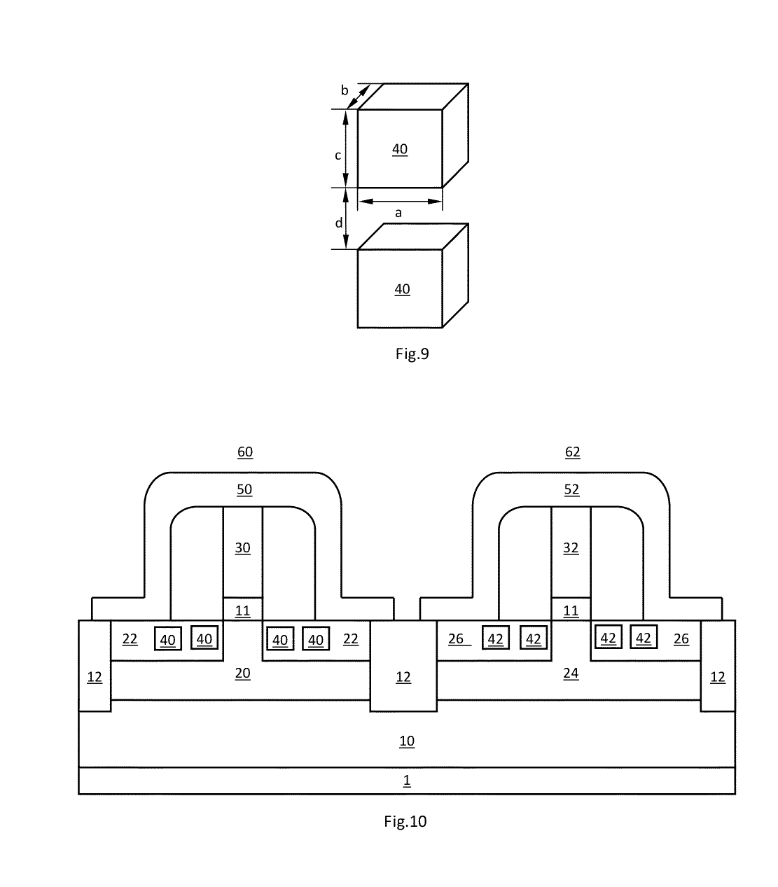

In this case the device structure is shown in FIG. 10. In the embodiment, holes locate in the source/drain region and have two. The junction depth of source and drain is 120 nm, height c of the holes is 40 nm, length a is 30 nm, distance d is 30 nm (shown in FIG. 3). The distance from the silicon surface is 40 nm. The holes are filled with the low Young's modulus material A1.

The above embodiments are only used to describe the technical solution of the invention in this case, or a better embodiment, not mean this invention is only limited to these embodiments, such as the shape of hole 40/42 is not limited to the above type of prism, also applied to spherical, ellipsoid, pyramid etc, the number of hole is not limited to the above 1, 2.

1-14. (canceled)

15. A method of utilizing a stress concentration effect to improve a channel stress of a MOS transistor, which includes a semiconductor substrate, a channel region, a source region, a drain region, a gate, a gate insulating layer, shallow trench isolated areas and a passivation layer, said method comprising:
forming holes at a certain distance away from the gate insulating layer; and
utilizing shapes of the holes and a difference of a Young's modulus between different materials to produce the stress concentration effect to enhance the channel stress of the channel region.

16. The method of claim 15, wherein the holes are formed by an etching process.

17. The method of claim 15, wherein the holes are filled with a material having a Young's modulus lower than that of Si.

18. The method of claim 15, wherein the holes are located below and/or above the gate insulating layer.

19. The method of claim 18, wherein the holes located below the gate insulating layer are 20-25 nm away from the gate insulating layer.

20. The method of claim 18, wherein the holes located above the gate insulating layer are 5-10 nm away from the gate insulating layer.

21. The method of claim 15, wherein the holes are located in source and drain regions.

22. The method of claim 21, wherein the holes are 30-50 nm away from a Si surface.

23. The method of claim 15, wherein the holes are located in a side wall region of the gate on both sides.

24. The method of claim 23, wherein the holes are 5-15 nm away from a Si surface.

25. The method of claim 15, wherein there are at least two holes.

26. The method of claim 15, wherein the holes are 2-40 nm away from each other.

27. The method of claim 15, wherein the holes are prisms.

28. The method of claim 27, wherein the prisms are regular tetragonal prisms.
